(19) United States
(12) Patent Application Publication
(10) Pub. No.: US 2023/0120408 A1
(43) Pub. Date: Apr. 20, 2023

(54) WAFER SCALE PRODUCTION OF SUPERCONDUCTING MAGNESIUM DIBORIDE THIN FILMS WITH HIGH TRANSITION TEMPERATURE

(71) Applicant: California Institute of Technology, Pasadena, CA (US)

(72) Inventors: Changsub Kim, Pasadena, CA (US); Daniel P. Cunnane, Pasadena, CA (US)

(73) Assignee: California Institute of Technology, Pasadena, CA (US)

(21) Appl. No.: 17/968,556

(22) Filed: Oct. 18, 2022

Related U.S. Application Data
(60) Provisional application No. 63/256,710, filed on Oct. 18, 2021.

(51) Int. Cl. H01L 39/14; H01L 39/24

(52) U.S. Cl. CPC H01L 39/141; H01L 39/2487

(57) ABSTRACT

A method of making a film comprising depositing magnesium and boron on a substrate; depositing a capping layer to form a capped film; and cooling the capped film so as to form a magnesium diboride film. The depositing may comprise tuning a ratio of the Mg to the B so as to tailor a resistivity of the magnesium diboride film anywhere in the range 10 μΩ*cm≤ρ≤500 mΩ*cm, and so as to form the magnesium diboride film comprising a superconductive film having a critical temperature greater than 10K or in a range 10K-40K. The magnesium diboride film can have an area greater than or equal to a circular area having a diameter of at least 4 inches; a thickness and sheet resistance varying by less than 10% over an entirety of the area; and a surface roughness less than 2 nm over the entirety of the area.

### CROSS REFERENCE TO RELATED APPLICATIONS

This application claims the benefit under 35 U.S.C. Section 119(e) of co-pending and commonly-assigned U.S. provisional patent application Ser. No. 63/256,710 filed on Oct. 18, 2021, by Changsub Kim and Daniel P. Cunnane, entitled “WAFER SCALE PRODUCTION OF SUPERCONDUCTING MAGNESIUM DIBORIDE THIN FILMS WITH HIGH TRANSITION TEMPERATURE,” client reference CIT-8539-P, which application is incorporated by reference herein.

### STATEMENT REGARDING FEDERALLY SPONSORED RESEARCH AND DEVELOPMENT

This invention was made with government support under Grant No. 80NMO0018D0004 awarded by NASA (JPL). The government has certain rights in the invention.

### BACKGROUND OF THE INVENTION

### 1. Field of the Invention

This invention relates to superconducting magnesium diboride films and methods of making the same.

### 2. Description of the Related Art

Magnesium diboride (MgB₂) is a material that can have a superconducting transition temperature as high as 39 Kelvin. However, conventional fabrication techniques cannot manufacture magnesium diboride films with mechanical and electrical properties that enable commercially practical fabrication of devices from the films. The present invention satisfies these needs by providing the superconducting films with improved mechanical properties such as wafer-scale smoothness and uniformity.

### SUMMARY OF THE INVENTION

Example methods, wafers, and compositions of matter according to embodiments described herein include, but are not limited to, the following.

1. A wafer, comprising:

a superconducting MgB₂ film, wherein the MgB₂ film:

has an area greater than or equal to a circular area having a diameter of at least 4 inches;

sheet resistance and a thickness varying by less than 10% over an entirety of the area; and

a surface roughness less than 1.5 nanometers (nm) over the entirety of the area.

2. The wafer of example 1, wherein the film has a resistivity ρ above 100 μΩ*cm or 100 μΩ*cm≤ρ≤10 mΩ*cm across an entirety of the area.

3. The wafer of example 1 or 2, wherein the MgB₂ film has a critical temperature of at least 15 Kelvin (K).

4. The wafer of any of the examples 1-3, further comprising a capping layer comprising Ta or B on the MgB₂ film.

5. A wafer, comprising:

a superconducting MgB₂ film, wherein the MgB₂ film:

has an area greater than or equal to a circular area having a diameter of at least 4 inches;

a resistivity ρ 25 μΩ*cm≤ρ≤50 μΩ*cm across an entirety of the area

a surface roughness of 2 nm or less across an entirety of the area,

a thickness and sheet resistance varying by less than 10% across the entirety of the area; and a critical temperature greater than 15K across the entirety of the area.

6. The wafer of example 5, wherein the MgB₂ film comprises a superconductive film having the critical temperature above 30 K.

7. The wafer of example 5 or 6, further comprising a capping layer comprising Ta or B on the MgB₂ film.

8. A method of making a film comprising magnesium diboride, comprising:

depositing magnesium (Mg) and boron (B) on a substrate so as to form an Mg—B composite;

depositing a capping layer to form a capped film, wherein the capping layer has a first melting temperature higher than a second melting temperature of the magnesium;

thermally annealing the capped film at a temperature; and

cooling the capped film so that a MgB₂ film is made.

9. The method of example 8, further comprising tuning a ratio of the Mg to the B so as to tailor:

a resistivity of the MgB₂ film anywhere in the range 10 μΩ*cm≤ρ≤500 mΩ*cm, and

a critical temperature of the MgB₂ film greater than 10K or in a range 10K-40K.

10. The method of example 8, further comprising selecting at least one of a thickness of the MgB₂ film or the Mg—B composite, a surface area of the substrate, a thickness of the capping layer, a ratio of the Mg to the B during the depositing, the temperature of the annealing, a hold time at the annealing temperature, co-depositing the B and the Mg or depositing the Mg and the B as alternating layers, and a cooling rate of the cooling, so as to form the MgB₂ film comprising a superconductor, wherein the MgB₂ film:

has an area greater than or equal to a circular area having a diameter of at least 4 inches;

the thickness varying by less than 10% over an entirety of the area;

a surface roughness less than 1.5 nm over the entirety of the area; and

a resistivity of the MgB₂ film in the range 50 μΩ*cm≤ρ≤100 mΩ*cm.

11. The method of example 8, further comprising selecting at least one of a thickness of the MgB₂ film or the Mg—B composite, a surface area of the substrate; a thickness of the capping layer, a ratio of the Mg to the B during the depositing, the temperature of the annealing, a hold time at the annealing temperature, co-depositing the B and the Mg or depositing the Mg and the B as alternating layers, and a cooling rate of the cooling, so as to form the MgB₂ film comprising a superconductor, wherein the MgB₂ film:

has an area greater than or equal to a circular area having a diameter of at least 4 inches;

a resistivity 25 μΩ*cm≤ρ≤50 μΩ*cm across an entirety of the area

a surface roughness of 2 nm or less across an entirety of the area,

a thickness varying by less than 10% across the entirety of the area; and

has a critical temperature greater than 15K across the entirety of the area.

12. The method of any of the examples 8-11, wherein the depositing comprises sputtering, atomic layer deposition, chemical vapor deposition, or electron beam deposition.

13. The method of any of the examples 8-12, wherein the annealing is:

at the temperature above the second melting temperature but below the first melting temperature so as to form the MgB₂ film into a superconductive film having a critical temperature above 30 Kelvin, or

at the temperature below both the second melting temperature so as to form a smoother MgB₂ film having a surface roughness of less than 2 nm.

14. The method of any of the examples 8-13, wherein the depositing comprises depositing alternating layers of the boron and the magnesium under magnesium rich conditions, and selecting at least one of a thickness of the MgB₂ film or a number of the layers to increase a critical temperature of the film above 15 K.

15. The method of any of the examples 8-14 further comprising controlling a hold time at the temperature depending on a thickness of the capping layer and so as to obtain a desired critical temperature for the MgB₂ film, wherein the hold time is maintained for a time long enough to promote growth of grains of the MgB₂ while avoiding escape of the Mg through the capping layer.

16. The method of any of the examples 8-15, wherein the capping layer comprises boron or Ta.

17. The method of any of the examples 8-16, further comprising selecting the capping layer having a thickness in a range 1-100 nm depending on at least one of:

a thickness of the MgB₂ film,

whether the boron and magnesium are co-deposited or as alternating layers,

the temperature of annealing and a hold time at the temperature, and wherein a thinner cap layer is used for at least one of a shorter hold time, a lower temperature, or a thinner MgB₂ film.

18. The method of any of the examples 8-16, wherein the depositing comprises depositing alternating layers of the boron and the magnesium to form the MgB₂ film with a higher surface roughness above 2 nm and a higher critical temperature above 15K.

19. The method of any of the examples 8-17, wherein the magnesium and the boron are co-deposited.

20. The method of any of the examples claim 8-19 further comprising co-depositing the boron and the magnesium and controlling a duration of the heating to form the film having a surface roughness below 2 nm.

21. The method of any of the examples 1-20, further comprising removing the capping layer.

22. A device manufactured from the film manufactured using method of any of the examples 8-21, wherein the device comprises a transmission line, a detector, a Josephson mixer, or a kinetic inductance device.

23. A composition of matter, wafer, or film manufactured using the method of any of the examples 8-21.

### BRIEF DESCRIPTION OF THE DRAWINGS

Referring now to the drawings in which like reference numbers represent corresponding parts throughout:

FIG. 1A illustrates a method and sputtering apparatus for depositing Mg and B to form an Mg—B composite film.

FIG. 1B illustrates a method and sputtering apparatus for depositing a capping layer on the Mg—B composite film.

FIG. 1C illustrates a method and apparatus for thermally annealing the Mg—B composite film.

FIG. 2A illustrates a wafer a manufactured using the method of FIGS. 1A-1C, showing an entirety of the wafer has mechanical and electrical properties useful for manufacturing devices, so that a wafer can be used to manufacture 1000's of devices, wherein the mechanical and electrical properties include wafer-scale smoothness and uniform superconducting films (uniform thickness and sheet resistance). FIG. 2B illustrates a side view of the wafer.

FIG. 3 illustrates the increase in critical temperature of the film, while tuning electrical properties, that can be achieved using the method according to the present invention illustrated in FIGS. 1A-1C.

FIGS. 4A-4B illustrates the uniformity measured using eddy current mapping, showing the sheet resistance of the MgB₂ film measured throughout the wafer and as determined from the eddy current mapping, wherein FIG. 4A shows 99% uniformity (i.e., sheet resistance and thickness of the Mg—B composite film within 1% across entire wafer) for the as-deposited film prior to annealing and FIG. 4B shows 95% uniformity (i.e. sheet resistance and thickness of the MgB₂ film within 5% across the entire wafer).

FIG. 5 illustrates how Mg:B ratio during deposition can be used to tune the resistivity of the Mg—B composite and MgB₂ films

FIG. 6 is a surface map, obtained using atomic force microscopy, of an MgB₂ film synthesized according to the methods described herein, showing a smooth MgB₂ film with the surface roughness of 0.476 nanometers rms.

FIG. 7 shows the MgB₂ film of FIG. 6 is a superconductive film having a critical temperature Tc of 32 Kelvins as well as the resistivity of across an entirety of a wafer. The film has a thickness of 80 nm and a surface roughness below 1 nm.

FIG. 8 is a flowchart illustrating a method of making a device from the wafer of FIG. 2.

FIG. 9 illustrates a kinetic inductance frequency multiplier useful as a THz source and having increased efficiency, manufactured using the MgB₂ film.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized, and structural changes may be made without departing from the scope of the present invention.

### Technical Description

Example MgB₂ Film Synthesis

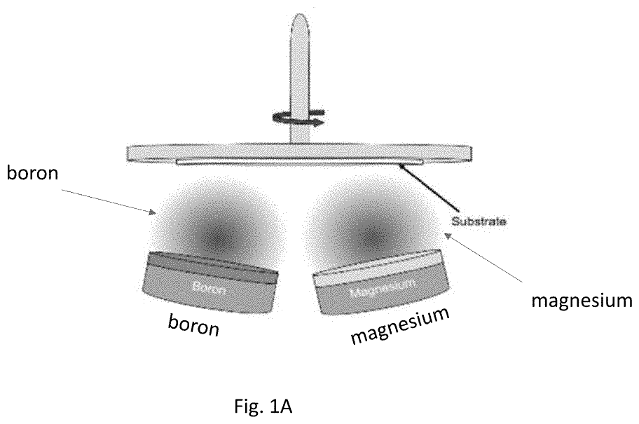

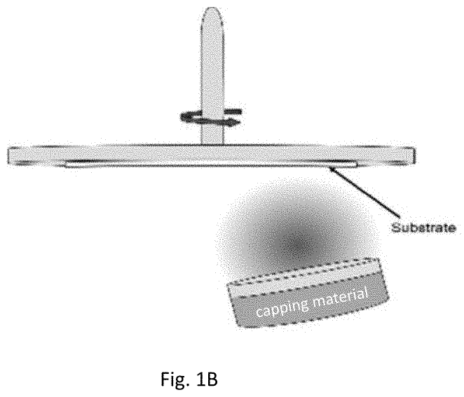

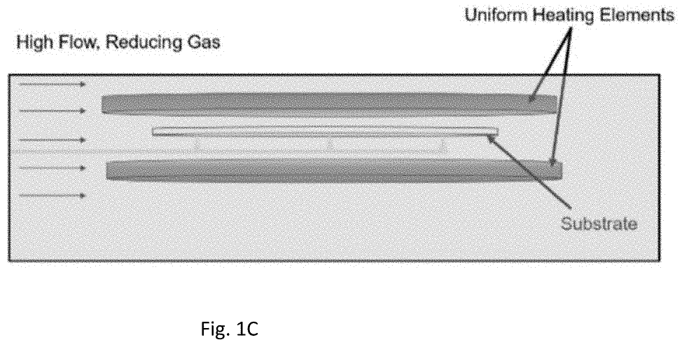

FIGS. 1A-1C is illustrates an example method and reactor/apparatus for making a film comprising a magnesium diboride film. The method comprises the following steps.

FIG. 1A represents depositing magnesium and boron on a substrate. Any substrate compatible with deposition of magnesium and boron, or MgB₂ formation, such as SiNₓ, silicon, or boron, can be used. Although FIG. 1A illustrates a sputtering (specifically co-sputtering) method and apparatus, the depositing can be performed using a variety of deposition techniques (and associated reactors) including, but not limited to, other types of sputter deposition, atomic layer deposition, metal organic chemical vapor deposition, chemical vapor deposition, and electron beam deposition.

The step comprises selecting an amount of the magnesium and boron that will initiate a reaction forming the MgB₂ film, during a subsequent annealing step. Amounts include stoichiometric amounts of magnesium, boron rich, or magnesium rich amounts.

The step further comprises tuning or selecting a ratio of the magnesium and the boron to form the MgB₂ film (after the subsequent annealing step) having a desired resistivity and superconducting transition temperature. For example, the resistivity can be tailored or tuned over a range from 10 μΩ*cm to 500 μΩ*cm by controlling the Mg/B ratio during the deposition process. In one or more examples, the Mg/B ratio is tuned such that for a resistivity in the range 50-500 μOhm*cm, the critical temperature Tc only varies from 26K-32K.

The boron and the magnesium may be deposited as alternating boron and magnesium layers, or co-deposited (e.g., co-sputtered). The deposition method, the amount of magnesium the number of alternating layers, and/or the thickness of the film, may be selected depending on the desired properties of the film.

For example, a thicker Mg layer (e.g., deposited under Mg rich conditions and/or in a structure comprising alternating Mg and Boron layers) may result in larger MgB₂ grain size and therefore higher critical temperature. Thus, the number of Mg and B layers and/or the thickness of the film may be selected to promote growth of MgB₂ grains and/or tune the critical temperature of the film.

In another example, depositing alternating layers of the boron and the magnesium forms an MgB₂ film (after the annealing step) with higher roughness and higher critical temperature, whereas co-depositing the magnesium and boron results in a smoother film and optionally lower critical temperature.

In one or more examples, the magnesium and boron are deposited to form a film having a thickness in a range of 1-1000 nm.

In typical examples, the film after the depositing step of FIG. 1A comprises a composite of magnesium and boron (e.g. Mg—B composite) which may comprise unreacted magnesium and boron.

FIG. 1B illustrates represents depositing a capping layer on the film comprising magnesium and boron to form a capped film, wherein the capping layer has a first melting temperature higher than a second melting temperature of the magnesium. Although FIG. 1B illustrates a sputter deposition technique, the depositing can be performed using a variety of deposition techniques (and associated reactors) including, but not limited to, atomic layer deposition, metal organic chemical vapor deposition, chemical vapor deposition, and electron beam deposition.

Without being bound by a particular scientific theory, boron capping layer is used to prevent evaporation or escape of Mg from the film, film decomposition, or other film degradation during the thermal annealing process. In some examples, stress from the capping layer (e.g., boron) can reduce roughness in the final product. Thus, capping layer thickness may be selected depending on the annealing conditions. For example, shorter annealing times, and/or lower annealing temperatures (e.g., <600° C.), and/or thinner MgB₂ films may require a thinner cap layer.

In various examples, the capping layer may have a thickness in a range of 1-1000 nm depending on the thickness of the MgB₂ layer and whether the boron and magnesium are deposited using co-sputtering or as alternating layers.

In various examples, the capping layer comprises, consists of, or consists essentially of at least one of boron, tantalum, a material that does not react with magnesium or boron and has a high melting temperature (e.g., above 1000° C.). In some examples, the capping layer comprises or consists of material that are less susceptible to oxidation.

In typical examples, the structure on the substrate after depositing the capping layer comprises the Mg—B composite comprising the magnesium, the boron, and the capping layer on top of the Mg—B composite.

FIG. 1C illustrates heating (e.g., thermally annealing) the capped film. Without being bound by a particular scientific theory, in this step, the magnesium and boron in the capped film may react to form MgB₂.

In one example, the thermal annealing is at an annealing temperature above 400° C. but below the first melting temperature of the capping layer, so as to form the MgB₂ film comprising a superconductive film having a critical temperature above 30 Kelvin.

In another example, the thermal annealing is at the annealing temperature (e.g., 600° C.) below both the second melting temperature (of the magnesium) and the first melting temperature (of the capping layer) so as to form a smoother superconductive MgB₂ film having a surface roughness of less than 2 nm.

The annealing temperature and hold time (time duration at the annealing temperature) can be varied to modify the properties of the film. Mg and Boron typically react quickly to form MgB₂ and it may be advantageous to promote continued growth of MgB₂ grains by extending the hold time. In some examples, higher Tc of the MgB₂ film is associated with larger grains which can be achieved using longer hold times. For example, hold time may be in a range of 5-10 minutes and/or depends on the thickness of the capping layer. In some examples, increasing the hold time promotes growth of the Mg grains (thereby increasing the critical temperature). In one or more examples, hold times above 10 minutes result in undesirable Mg escapes through the cap layer and degradation of MgB₂ film properties. After annealing, the MgB₂ film is cooled. In some examples, the capped MgB₂ film is cooled at a slower rate to avoid cracking of the film.

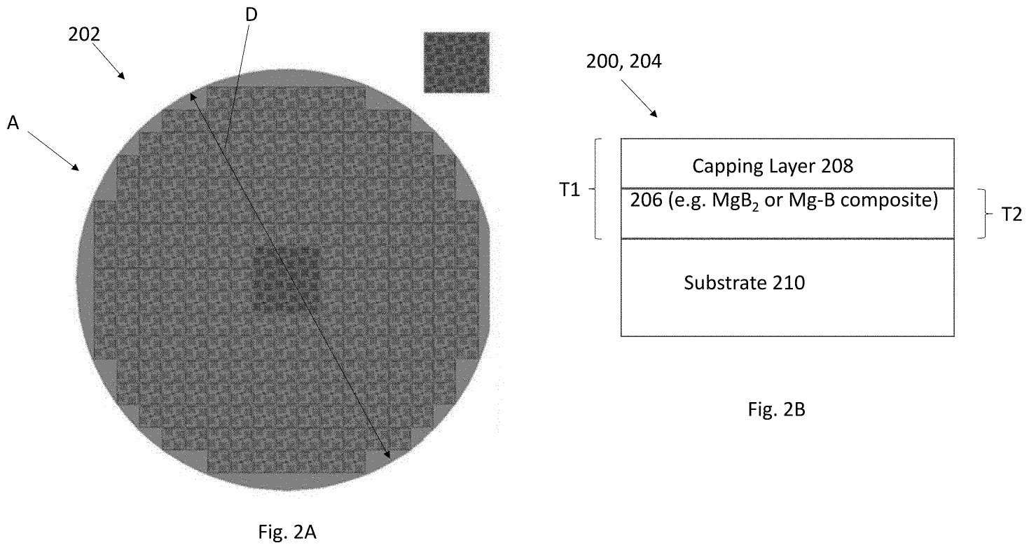

FIGS. 2A-2B represent the end result, a composition of matter 200 comprising a wafer 202 comprising a film 204 including magnesium and boron (typically as MgB₂), and the capping layer. FIG. 2A is a top view, and FIG. 2B shows a side view illustrating the wafer comprises the one or more layers 206 comprising the magnesium and boron (e.g., MgB₂ film 206) and the capping layer 208 on top. Without being bound by scientific theory, the composition of matter may comprise a superconductor or superconducting film 206 comprising the magnesium and the boron layer(s) 206 (e.g., MgB₂); and the capping layer 208 or capping material (e.g., boron or tantalum) on top.

In some examples, the capping layer is subsequently removed so that the superconductor/superconductive film comprising the MgB₂ film remains. In yet further examples, the substrate 210 may also be at least partially removed. In yet further examples, additional elements may be added to further tailor the properties of the film.

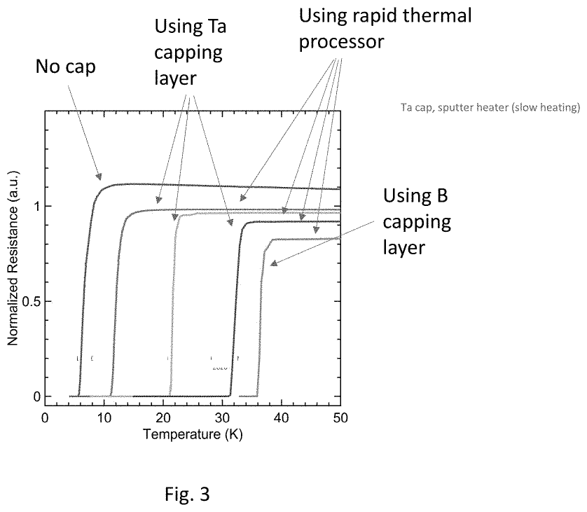

FIG. 3 illustrates the effect of capping layer and thermal annealing on superconductive properties of the film.

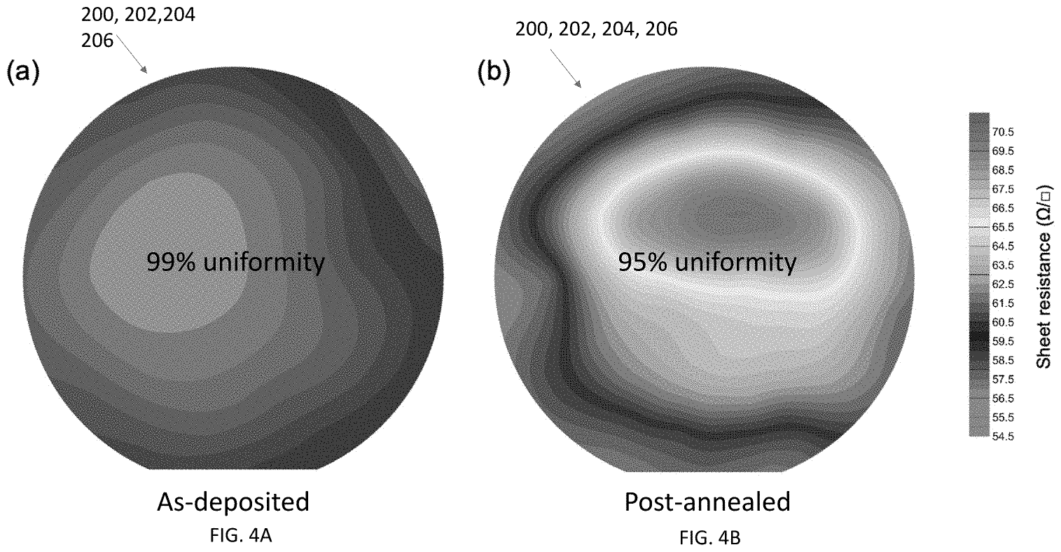

FIGS. 4A-4B show the uniformity (of thickness T and sheet resistance) of the film 204 (comprising magnesium and boron (as an Mg—B composite or MgB₂ film) and the capping layer) measured using eddy current mapping (sheet resistance throughout wafer).

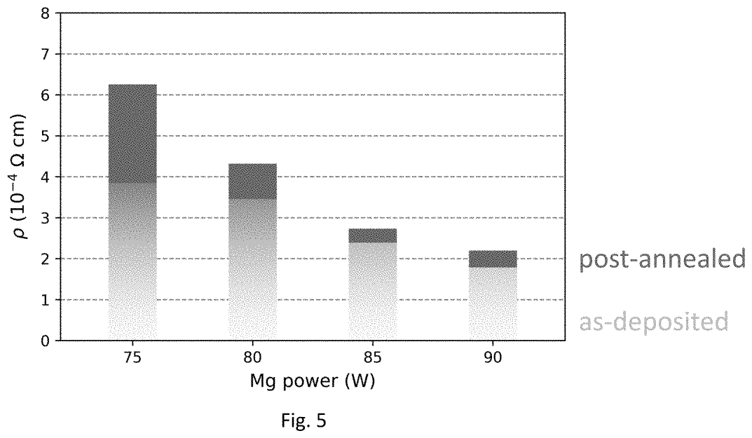

FIG. 5 shows how the resistivity of the film 204 (e.g., MgB₂ film 206) can be tuned using the Mg:B ratio during deposition (in this case the power used for the Mg source during sputtering).

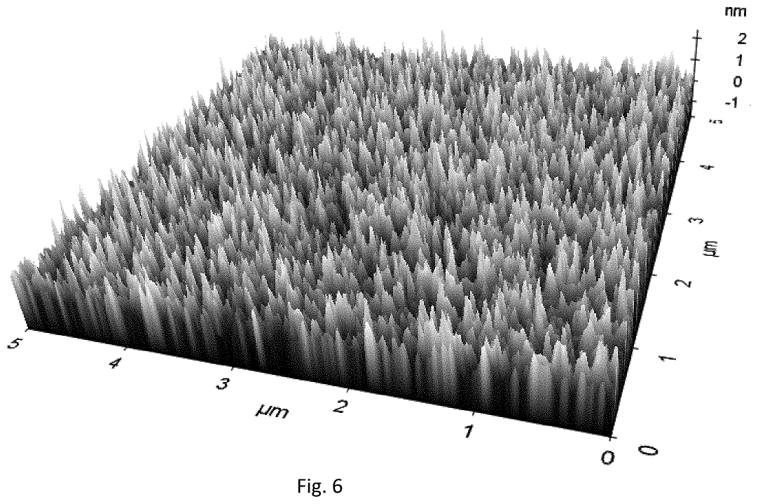

FIG. 6 illustrates measured surface roughness of the film 204 comprising (e.g., comprising the superconducting MgB₂ 206 and the capping layer 208) which is representative of the surface roughness across an entirety of the wafer.

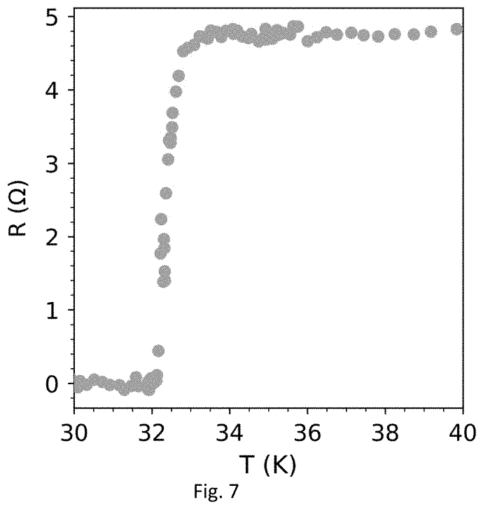

FIG. 7 illustrates the superconductive properties of the film 204 comprising the MgB₂ film 205.

The results shown in FIGS. 4A-4B and 6-7 were obtained by sputter depositing 1:2 atomic ratio of Mg:B onto a substrate. However, other Mg:B ratios in the range of 0.8:2 to 1.5:2 are also effective and producing uniform superconductive films with roughness less than 2 nm and critical temperature above 15K and resistivities in the range shown in FIG. 5. Note that deposition conditions should take into account that magnesium readily oxidizes in the existence of even the slightest trace amount of oxygen inside the vacuum chambers—i.e. depending on the base pressure of the chamber, the total amount of elemental magnesium may vary. For the examples measured in FIGS. 4A-4B and 6-7, the total thickness of Mg—B composite film was 50 nm and a thin (20 nm) layer of boron was sputtered to cap the Mg—B composite film, and the film was then annealed inside a rapid thermal processor (RTP) at 600° C. for 10 minutes using a ramp rate of 1 degree per second. However, other temperatures in the range: 500˜630° C. and typical annealing times in the range: 3˜30 minutes can be used (shorter times for thinner films, and longer times for thicker films).

The results in FIGS. 4A-4B, 6, and 7 were obtained for the same wafer 202. Because boron in the capping layer is insulating, it does not show up (or affect) the resistivity/sheet resistance/superconducting transition measurements. The measured roughness and thickness uniformity is for the MgB₂ film (since boron capping layer roughness will be flat without MgB₂).

Thickness (unless otherwise stated) refers to Mg—B composite (pre-annealed) or MgB₂ thickness (post-annealed).

Example films, compositions of mater, wafers, and methods include, but are not limited to, the following examples.

1. FIGS. 2 and 4-7 illustrate a composition of matter 200, wafer 202, or film 204, comprising or consisting essentially of magnesium, boron, and optionally a capping layer 208 or capping material. The composition of matter 200 may comprise magnesium and boron, or a compound comprising magnesium and boron comprising a superconductor, or a film or superconductor comprising magnesium and boron, or film or superconductor comprising a compound including magnesium and boron. The magnesium and boron are typically reacted to form MgB₂ so that the film 204 comprises an MgB₂ film 206 and the capping layer 208 optionally on the MgB₂ film 206. The film 204, 206 has an area A defined by a diameter D of at least 4 inches (e.g., 4≤D≤12 inches), or an equivalent area, a uniform sheet resistance and uniform thickness T1 or T2 as characterized by the sheet resistance and thickness T1 or T2 varying by less than 10% or less than 3% (e.g., 1%≤thickness variation≤10%) over the area, and a surface roughness Ra less than 1.5 nm over an entirety of the area (e.g., 0.2 nm≤R≤1.5 nm).

2. The composition of matter of example 1, wherein the film 204 (typically the MgB₂ film 206) has a resistivity ρ above 100 μΩ*cm or 100 μΩ*cm≤ρ≤500 μΩ*cm or 100μΩ*cm≤ρ≤10 mΩ*cm (see e.g. FIG. 5).

3. The composition of matter of example 1 or 2, comprising the film 204 comprises a superconductor or superconductive film 206 (MgB₂ film) having a critical temperature above 15K (see e.g. FIG. 7). FIG. 3 illustrates how the use of the capping layer 208 results in a film having increased critical temperature without compromising resistivity properties.

4. FIGS. 2 and 4-7 illustrate a composition of matter 200 or wafer 202 comprising a film 204, 206 comprising or consisting essentially of magnesium, boron, and optionally a capping layer 208. The composition of matter 200 may comprise magnesium and boron, or a compound comprising magnesium and boron comprising a superconductor, or a film or superconductor comprising magnesium and boron, or film or superconductor comprising a compound including magnesium and boron. In typical examples, the magnesium and boron are reacted to form MgB₂ so that the film 204, 206 comprises or consists essentially of an MgB₂ film 206 and the capping layer optionally on the MgB₂ film. The film 204, 206 has an area defined by a diameter D of at least 4 inches (e.g., 4≤D≤12 inches), a resistivity between 25-50 microohmcm (25 μΩ*cm≤ρ≤50 μΩ*cm), a surface roughness of 2 nm or less (e.g., 0.2 nm≤R≤2 nm) over an entirety of the area of the film 202, a uniform sheet resistance and uniform thickness T1, T2 as characterized by the thickness T1 or T2 varying by less than 10% or less than 3% over an entirety of the area (e.g., 1%≤thickness variation≤10%), and the film 204, 206 comprises a superconductor having a critical temperature greater than 15 K.

5. The composition of matter of example 4, wherein the film 204 comprises the MgB₂ film 206 having a critical temperature above 30 K, as illustrated in FIG. 7.

6. The composition of matter of any of the examples 1-5, further comprising a wafer 202 comprising the film 204.

7. The composition of matter of example 6, wherein the film 204 is on a substrate.

8. A method of making a film comprising magnesium and boron (magnesium diboride), comprising:

depositing magnesium and boron on a substrate so as to form an Mg—B composite;

depositing a capping layer to form a capped film, wherein the capping layer has a first melting temperature higher than a second melting temperature of the magnesium;

thermally annealing the capped film at a temperature; and

cooling the capped film, so that a MgB₂ film is made.

9. The method of example 8, further comprising tuning a ratio of the Mg to the B so as to tailor:

a resistivity of the MgB₂ film anywhere in the range 10 μΩ*cm≤ρ≤500 mΩ*cm, and a critical temperature of the MgB₂ film greater than 10K or in a range 10K-40K.

10. The method of example 8, further comprising selecting at least one of a thickness of the Mg—B composite or the MgB₂ film, a surface area of the substrate, a thickness of the capping layer, a ratio of the Mg to the B during the depositing, the temperature of the annealing, a hold time at the annealing temperature, co-depositing the B and the Mg or depositing the Mg and the B as alternating layers, and a cooling rate of the cooling, so as to form the film comprising a superconductor, wherein the MgB₂ film (e.g., with or without the capping layer):

has an area greater than or equal to a circular area having a diameter of at least 4 inches;

the thickness and sheet resistance varying by less than 10% over an entirety of the area;

a surface roughness less than 1.5 nm over the entirety of the area; and

a resistivity of the film (comprising magnesium and boron, e.g., MgB₂) in the range 50 μΩ*cm≤ρ≤100 mΩ*cm.

11. The method of example 8, further comprising selecting at least one of a thickness of the Mg—B composite or the MgB₂ film, a surface area of the substrate; a thickness of the capping layer, a ratio of the Mg to the B during the depositing, the temperature of the annealing, a hold time at the annealing temperature, co-depositing the B and the Mg or depositing the Mg and the B as alternating layers, and a cooling rate of the cooling, so as to form the film comprising a superconductor, wherein the MgB₂ film (e.g., with or without the capping layer):

has an area greater than or equal to a circular area having a diameter of at least 4 inches;

a resistivity 25 μΩ*cm≤ρ≤50 μΩ*cm across an entirety of the area

a surface roughness of 2 nm or less across an entirety of the area,

a thickness and sheet resistance varying by less than 10% across the entirety of the area; and

the superconductor has a critical temperature greater than 15K across the entirety of the area.

12. The method of any of the examples 8-11, wherein the depositing comprises sputtering, atomic layer deposition, chemical vapor deposition, or electron beam deposition.

13. The method of any of the examples 8-11, wherein the annealing is:

at the temperature above the second melting temperature but below the first melting temperature so as to form the MgB₂ film comprising the superconductor having a critical temperature above 30 Kelvin, or

at the temperature below both the second melting temperature so as to form a smoother MgB₂ film having a surface roughness of less than 2 nm.

14. The method of any of the examples claim 8-13, wherein the depositing comprises depositing alternating layers of the boron and the magnesium under magnesium rich conditions, and selecting at least one of a thickness of the Mg—B composite or the MgB2 film and/or a number of the layers to increase a critical temperature of the MgB₂ film above 15 K.

15. The method of any of the examples claim 8-14 further comprising controlling a hold time at the temperature depending on a thickness of the capping layer and so as to obtain a desired critical temperature for the superconductor/MgB₂ film, wherein the hold time is maintained for a time long enough to promote growth of grains of the MgB₂ while avoiding escape of the Mg through the capping layer.

16. The method of any of the examples claim 8-15, wherein the capping layer comprises boron or Ta.

17. The method of claim 12, further comprising selecting the capping layer having a thickness in a range 1-100 nm depending on at least one of:

a thickness of the film/MgB₂ film,

whether the boron and magnesium are co-deposited or as alternating layers,

the temperature of annealing and a hold time at the temperature, and wherein a thinner cap layer is used for at least one of a shorter hold time, a lower temperature, or a thinner film.

18. The method of any of the examples claim 8-17, wherein the depositing comprises depositing alternating layers of the boron and the magnesium to form the MgB₂ film with a higher surface roughness above 2 nm and a higher critical temperature above 15K.

19. The method of any of the examples 8-17, wherein the magnesium and the boron are co-deposited.

20. The method of any of the examples claim 8-19 further comprising co-depositing the boron and the magnesium and controlling a duration of the heating to form the MgB₂ film having a surface roughness below 2 nm.

21. The method of any of the examples 1-20, further comprising removing the capping layer.

22. The composition of matter of any of the examples 1-7, wherein the composition of matter 200 comprises or consists essentially of the magnesium, the boron, and optionally tantalum or a capping moiety or capping material or additional boron.

23. The composition of matter of any of the examples 1-7, comprising a superconductor 206 comprising the magnesium and the boron.

24. The composition of matter of any of the examples 1-7 or 22-23, wherein the magnesium and the boron form MgB₂.

25. The composition of matter of any of the examples 1-7 or 22-25, wherein the sheet resistance of the MgB₂ film 206 or superconductor varies by less than 10% or less than 3% (e.g., 1%≤sheet resistances≤10%) over the area.

26. A composition of matter, wafer, or film manufactured using the method of any of the examples 8-21.

27. A device manufactured from the film manufactured using method of any of the examples 8-21 or from the composition of matter of any of the examples 1-7 or 22-25, wherein the device comprises a transmission line, a detector, a Josephson mixer, or a kinetic inductance device.

28. The device, wafer, method, or composition of matter of any of the examples, wherein the transition temperature comprises the critical temperature Tc below which a resistance of the film drops to zero.

29. The composition of matter of any of the examples, wherein the film 204 does not include the capping layer (capping layer has been removed).

30. The composition of matter of any of the examples, wherein the film 204 includes a capping layer 208.

Example Device Fabrication

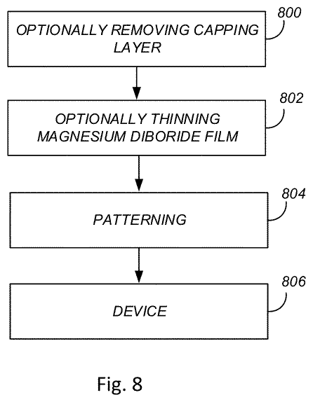

FIG. 8 is a flowchart illustrating a method of making a device using the wafer manufactured according to the methods described herein.

Block 800 represents optionally removing the capping layer from the MgB₂ film. (e.g., using argon ion milling).

Block 802 represents optionally etching (e.g., using argon ion milling) so as to thin the MgB₂ film, e.g., to a thickness below 10 nm.

Block 804 represents patterning the film into a device. In one or more examples, the patterning comprises depositing a hardmask (e.g., titanium) on the thinned superconductive film, wherein the hardmask comprises a material etched at a much slower rate than the MgB₂ using argon ion milling, and etching a pattern into the film using the hardmask. In one example, the patterning comprises depositing a hardmask comprising a bilayer comprising a titanium layer on top of a gold layer; removing the titanium layer using a reactive ion etch (RIE); and removing the gold and portions of the MgB₂ using argon ion milling.

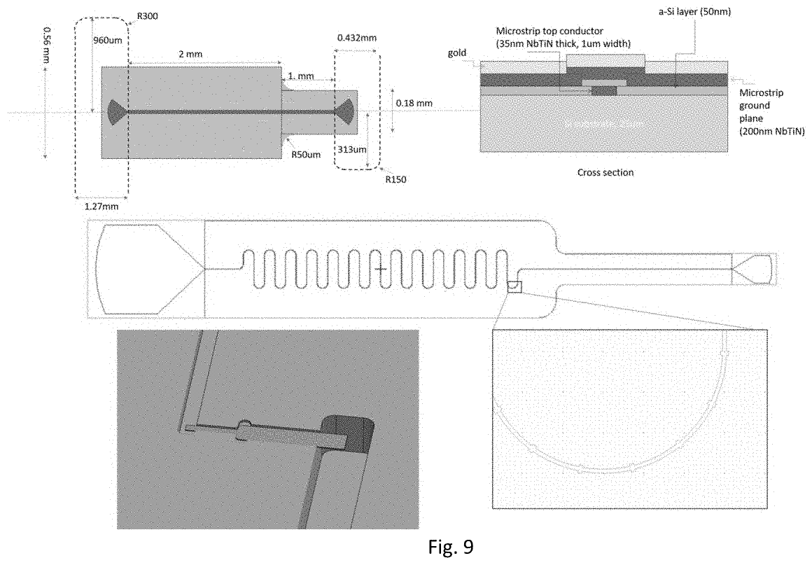

Block 806 represents the end result, a device comprising the MgB₂ film synthesized in accordance with the methods described herein. Example devices include, but are not limited to, a transmission line, a superconducting interferometer [1], a detector (e.g., a hot electron bolometer or a superconducting single photon detector [2], [3], a kinetic inductance bolometer [4], a Josephson mixer, a superconducting amplifier [5] or a kinetic inductance frequency multiplier (FIG. 9).

### REFERENCES

The following references are incorporated by reference herein.
[1] Superconducting On-chip Fourier Transform Spectrometer, Journal of Low Temperature Physics (2020) 200:342-352
[2] Fabrication of a MgB2 nanowire single-photon detector using Br2-N2 dry etching, Applied Physics Express 7, 103101 (2014)
[3] High-Operating-Temperature Superconducting Nanowire Single Photon Detectors based on Magnesium Diboride, CLEO 2017 © OSA 2017, FF1E.7
[4] Arrays of membrane isolated yttrium-barium-copper-oxide kinetic inductance, Journal of Applied Physics 115, 234509 (2014); doi: 10.1063/1.4884437
[5] A wideband, low-noise superconducting amplifier with high dynamic range, nature physics Vol. 8, August 2017.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A wafer, comprising:
a superconducting MgB₂ film, wherein the MgB₂ film:
has an area greater than or equal to a circular area having a diameter of at least 4 inches;
a sheet resistance and a thickness varying by less than 10% over an entirety of the area; and
a surface roughness less than 1.5 nanometers (nm) over the entirety of the area.

2. The wafer of claim 1, wherein the film has a resistivity ρ above 100 μΩ*cm or 100 μΩ*cm≤ρ≤10 mΩ*cm across an entirety of the area.

3. The wafer of claim 2, wherein the film has a critical temperature of at least 15K.

4. The wafer of claim 1, further comprising a capping layer comprising Ta or B on the MgB₂ film.

5. A wafer, comprising:
a superconducting MgB₂ film, wherein the MgB₂ film:
has an area greater than or equal to a circular area having a diameter of at least 4 inches;
a resistivity ρ 25 μΩ*cm≤ρ≤50 μΩ*cm across an entirety of the area
a surface roughness of 2 nm or less across an entirety of the area,
a sheet resistance and a thickness varying by less than 10% across the entirety of the area; and
a critical temperature greater than 15K across the entirety of the area.

6. The wafer of claim 5, wherein the MgB₂ film comprises a superconductive film having the critical temperature above 30 K.

7. The wafer of claim 5, further comprises a capping layer comprising Ta or B on the MgB₂ film.

8. A method of making a film comprising magnesium diboride, comprising:
depositing magnesium and boron on a substrate so as to form an Mg—B composite;
depositing a capping layer to form a capped film, wherein the capping layer has a first melting temperature higher than a second melting temperature of the magnesium;
thermally annealing the capped film at a temperature; and
cooling the capped film so that a MgB₂ film is made.

9. The method of claim 8, further comprising tuning a ratio of the Mg to the B so as to tailor:
a resistivity of the MgB₂ film anywhere in the range 10 μΩ*cm≤ρ≤500 mΩ*cm, and
a critical temperature of the MgB₂ film greater than 10K or in a range 10K-40K.

10. The method of claim 8, further comprising selecting at least one of a thickness of the MgB₂ film or the Mg—B composite, a surface area of the substrate, a thickness of the capping layer, a ratio of the Mg to the B during the depositing, the temperature of the annealing, a hold time at the annealing temperature, co-depositing the B and the Mg or depositing the Mg and the B as alternating layers, and a cooling rate of the cooling, so as to form the MgB₂ film comprising a superconductor, wherein the MgB₂ film:
has an area greater than or equal to a circular area having a diameter of at least 4 inches;
the thickness varying by less than 10% over an entirety of the area;
a surface roughness less than 1.5 nm over the entirety of the area; and
a resistivity of the MgB₂ film in the range 50 μΩ*cm≤ρ≤100 mΩ*cm.

11. The method of claim 8, further comprising selecting at least one of a thickness of the MgB₂ film or the Mg—B composite, a surface area of the substrate; a thickness of the capping layer, a ratio of the Mg to the B during the depositing, the temperature of the annealing, a hold time at the annealing temperature, co-depositing the B and the Mg or depositing the Mg and the B as alternating layers, and a cooling rate of the cooling, so as to form the MgB₂ film comprising a superconductor, wherein the MgB₂ film:
has an area greater than or equal to a circular area having a diameter of at least 4 inches;
a resistivity 25 μΩ*cm≤ρ≤50 μΩ*cm across an entirety of the area
a surface roughness of 2 nm or less across an entirety of the area,
a thickness varying by less than 10% across the entirety of the area; and
has a critical temperature greater than 15K across the entirety of the area.

12. The method of claim 8, wherein the depositing comprises sputtering, atomic layer deposition, chemical vapor deposition, or electron beam deposition.

13. The method of claim 8, wherein the annealing is:
at the temperature above the second melting temperature but below the first melting temperature so as to form the MgB₂ film into a superconductive film having a critical temperature above 30 Kelvin, or
at the temperature below both the second melting temperature so as to form a smoother MgB₂ film having a surface roughness of less than 2 nm.

14. The method of claim 8, wherein the depositing comprises depositing alternating layers of the boron and the magnesium under magnesium rich conditions, and selecting at least one of a thickness of the MgB₂ film or a number of the layers to increase a critical temperature of the film above 15 K.

15. The method of claim 8 further comprising controlling a hold time at the temperature depending on a thickness of the capping layer and so as to obtain a desired critical temperature for the MgB₂ film, wherein the hold time is maintained for a time long enough to promote growth of grains of the MgB₂ while avoiding escape of the Mg through the capping layer.

16. The method of claim 8, wherein the capping layer comprises boron or Ta.

17. The method of claim 12, further comprising selecting the capping layer having a thickness in a range 1-100 nm depending on at least one of:
a thickness of the MgB₂ film,
whether the boron and magnesium are co-deposited or as alternating layers,
the temperature of annealing and a hold time at the temperature, and wherein a thinner cap layer is used for at least one of a shorter hold time, a lower temperature, or a thinner MgB₂ film.

18. The method of claim 8, wherein the depositing comprises depositing alternating layers of the boron and the magnesium to form the MgB₂ film with a higher surface roughness above 2 nm and a higher critical temperature above 15K.

19. The method of claim 8, wherein the magnesium and the boron are co-deposited.

20. The method of claim 8 further comprising co-depositing the boron and the magnesium and controlling a duration of the heating to form the MgB₂ film having a surface roughness below 2 nm.
